(19) United States
(12) Patent Application Publication
(10) Pub. No.: US 2009/0183761 A1
(43) Pub. Date: Jul. 23, 2009

(54) SOLAR ENERGY ABSORBING DEVICE

(76) Inventor: Wen-Wei Lin, Taipei County (TW)

Correspondence Address: WEN-WEI LIN, 235 Chung - Ho, Box 8-24, Taipei, TW

(21) Appl. No.: 12/017,060

(22) Filed: Jan. 21, 2008

(51) Int. Cl. H01L 31/052

(52) U.S. Cl. 136/246

(57) ABSTRACT

A solar energy absorbing device comprises a plurality of magnifying glasses which are formed as an integral body and are combined by adhesion or by using a frame for absorbing solar energy; a plurality of focusing sheets spaced from the magnifying glasses and for focusing the light from the magnifying glasses; a plurality of optical fibers connected to the focusing sheets for transferring the light focused by the focusing sheets; and at least one photoelectric converter for converting the solar energy into electric energy.

### FIELD OF THE INVENTION

The present invention relates to solar energy absorbing devices, and particularly to a solar energy absorbing device, wherein it is suitable in any season and can absorb light energy from any orientation with a larger light absorbing area. Furthermore, the present invention has a higher efficiency and the solar energy can be retained well. The light energy can be transferred to a farther place and the present invention is suitable for a wide light wave band.

### BACKGROUND OF THE INVENTION

Referring to FIGS. 1 and 2, the prior art solar energy absorbing structure is illustrated. In the prior art, the solar energy A is absorbed by solar energy plates B which are installed to retaining frames. Then the absorbed solar energy C is transferred by a medium D to a photoelectric converter E for converting light energy to electric energy. Then a DC to AC converter C serves to convert DC current into AC current for being provided to an AC device I or an industrial power device J or is stored in a solar energy battery F to supply to a DC device H.

However due to the design of the retaining frame is a plane so that solar energy is absorbed at finite time period, while when other time that the direction of the sun is out of the absorbing range, the solar energy plate can not absorb solar energy. Further the orientation of the sun is confined by seasons. Thus, if the retaining frame is fixed, the absorbing of the solar energy can not achieve an optimum efficiency.

Furthermore, the prior art solar energy plate is formed by a plurality of heat absorbing unit B, but the absorbing unit B can not magnify the heat power and the light is not focused so as to have higher energy efficiency. Furthermore, the prior art medium D has a lower transmission efficiency. The solar energy can not be effectively accumulated. The photoelectric converter will further reduce the power collected.

However from above discussion, it is known that the prior art has the following disadvantages. The solar energy is collected at a part of daytime. The collected light is not magnified and focused so that the power efficiency is low. The power transmission is low and the solar energy plates is unadjustable so that the orientation and direction is unadjustable to have better efficiency for absorbing light.

### SUMMARY OF THE INVENTION

Accordingly, the primary object of the present invention is to provide a solar energy absorbing device, wherein it is suitable in any season and can absorb light energy from any orientation with a larger light absorbing area. Furthermore, the present invention has a higher efficiency and the solar energy can be retained well. The light energy can be transferred to a farther place and the present invention is suitable for a wide light wave band.

To achieve above objects, the present invention provides a solar energy absorbing device, comprising: a plurality of magnifying glasses which are formed as an integral body and are combined by adhesion or by using a frame for absorbing solar energy; a plurality of focusing sheets spaced from the magnifying glasses and for focusing the light from the magnifying glasses; a plurality of optical fibers connected to the focusing sheets for transferring the light focused by the focusing sheets; and at least one photoelectric converter for converting the solar energy into electric energy.

The photoelectric converter is connected to a DC to AC converter to convert the DC current into AC current so as to be used in an AC device or in an industrial power device, or the power is stored in a solar energy battery. The plurality of magnifying glasses are formed as semi-sphere. The focusing sheet is placed at a focus point of a respective magnifying glass for focusing light from the magnifying glass effectively.

The various objects and advantages of the present invention will be more readily understood from the following detailed description when read in conjunction with the appended drawing.

### BRIEF DESCRIPTION OF THE DRAWINGS

FIG. 1 is a perspective view showing the prior art solar energy absorbing structure.

FIG. 2 shows the prior art solar energy absorbing and converting process.

FIG. 3 is a schematic view showing the outlook of the present invention.

FIG. 4 is a perspective view about the structure of the present invention.

FIG. 5 shows the structure about the application of the present invention.

FIG. 6 shows another perspective view of the present invention.

FIG. 7 shows a further perspective view of the present invention.

FIG. 8 shows the structure of the application of the present invention.

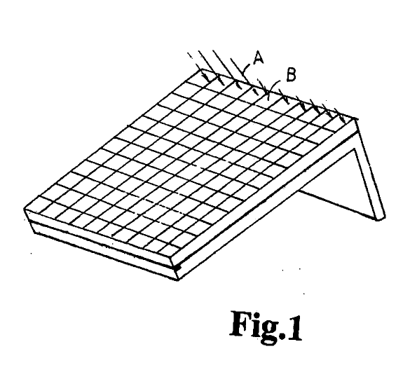

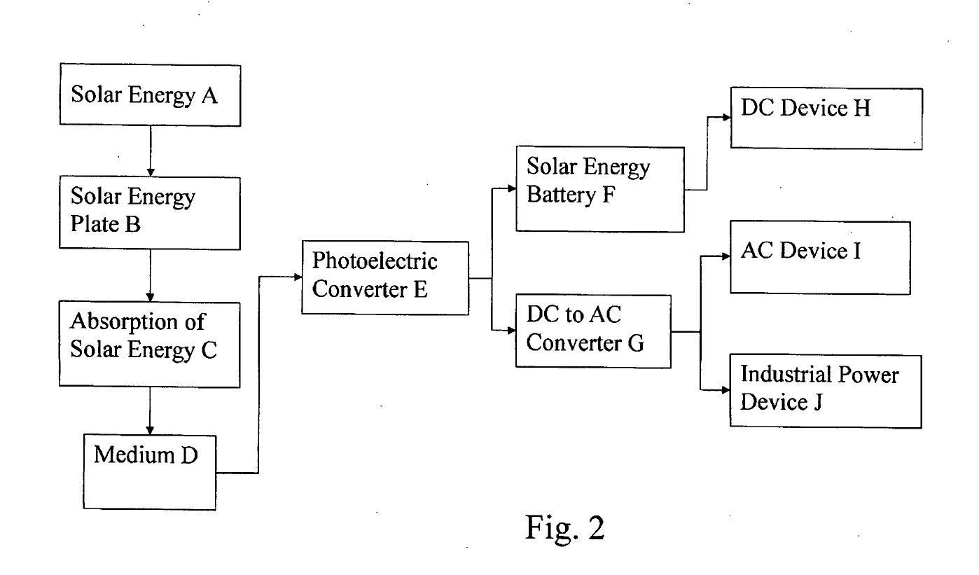

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

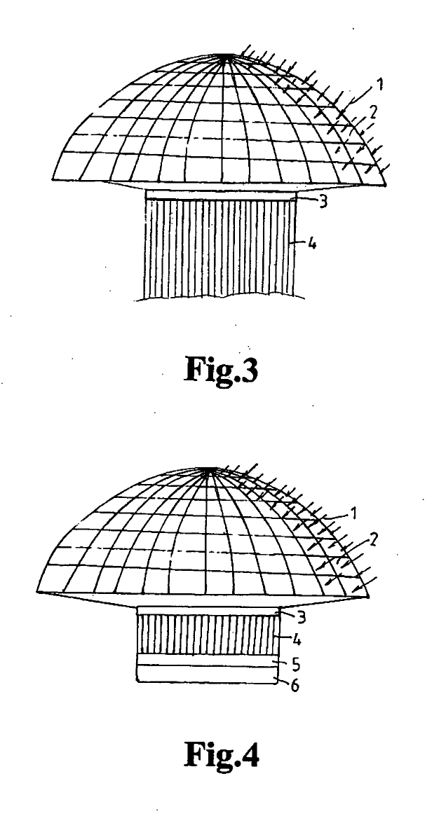

Referring to FIGS. 3 to 5, the structure of the present invention will be described herein.

A plurality of magnifying glasses 2 which are formed as semi-sphere and are combined by adhesion or by using a frame for absorbing solar energy at daytime from any orientation and with a larger light absorption area. However, in the present invention, it is only necessary to arrange the magnifying glasses 2 through 360 degrees to absorb solar energy at any orientation.

A plurality of focusing sheets 3 are spaced from the magnifying glasses 2 and are for focusing the light from the magnifying glasses 2. In this the present invention, the focusing sheets 3 are installed at a lower side of the magnifying glasses 2.

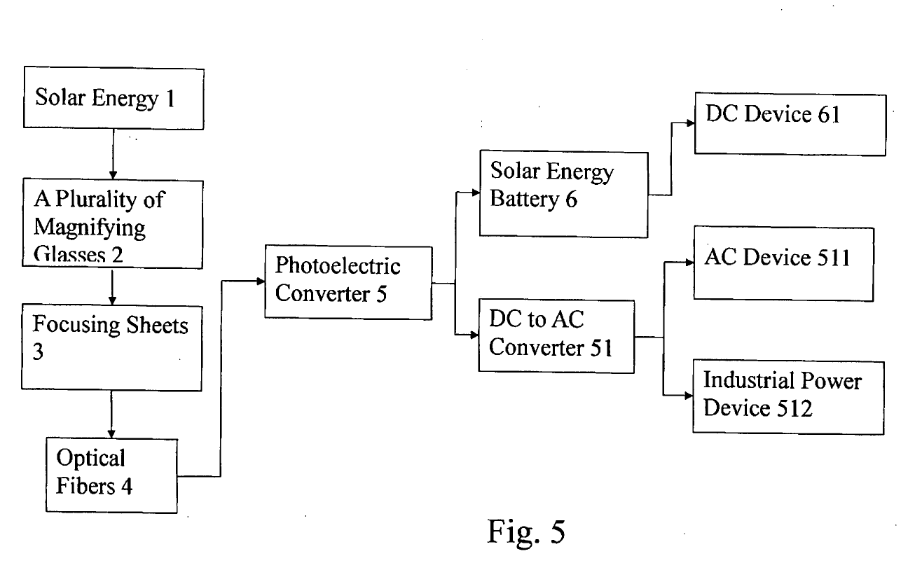

A plurality of optical fibers 4 serves for transferring the light focused by the focusing sheets 3. In this embodiment, the optical fibers 4 are arranged at a lower side of the focusing sheets 3. The optical fibers 4 are effective in the transformation of solar energy with a wide orientation and can transfer the light through a long length. Further solar energy 1 can be retained therein effectively. The optical fibers 4 can guide light to many places, such as indoor illumination, or the places, or the solar energy 1 is guided to a photoelectric converter 5 for converting the solar energy 1 into electric energy. Then a DC to AC converter 51 serves to convert the DC current into AC current so as to be used in an AC device 511 or in an industrial power device 512, or the power is stored in a solar energy battery 6 so as to supply DC current to a DC device 61, as illustrated in FIGS. 4 and 5.

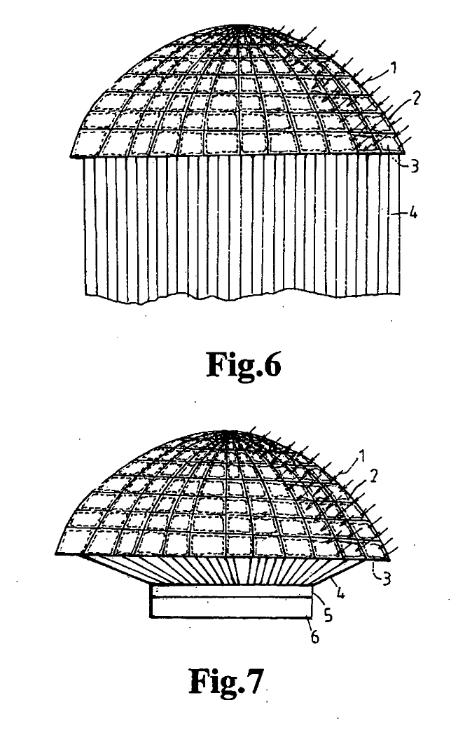

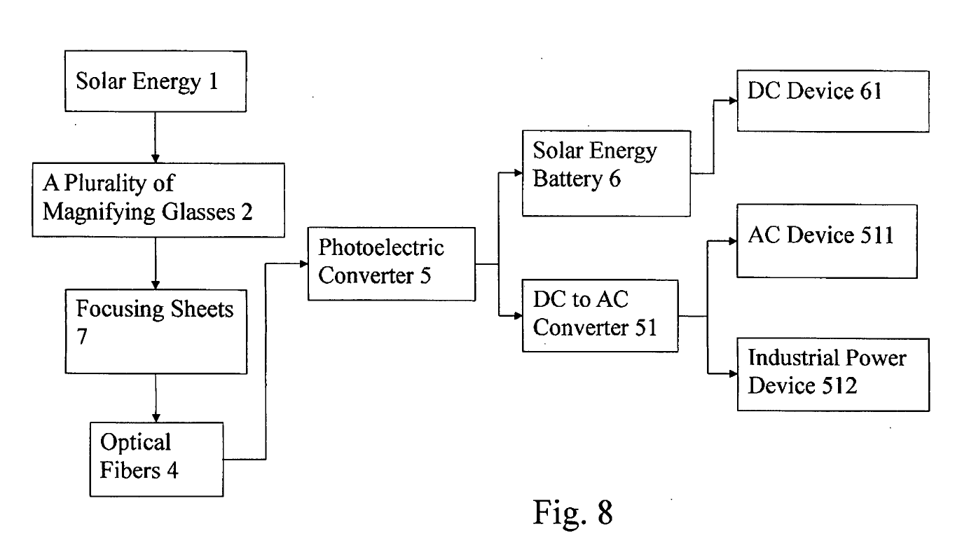

Referring to FIGS. 6 to 8, the other embodiments of the present invention is illustrated. It is illustrated, the focusing sheet 3 is placed below a respective magnifying glass 2 and the optical fiber 4 is connected at a lower end of the respective focusing sheet 3 as illustrated in FIG. 7. In FIGS. 7 and 8, is illustrated that the solar energy 1 is concentrated to the photoelectric converter 5 so as to convert solar energy 1 into electric energy. Then the power is transferred through the DC to AC converter 51 to convert the DC power into AC power for being supplied to an AC device 511 or an industrial power device 512, or stored in the solar energy battery 6 for further supplying DC power to a DC device 61. In the present invention, it is illustrated that in the present invention the focusing sheet 3 can be installed in the respective magnifying glass 2.

In summary, the structure of the present invention can absorb solar energy 1 and converts the solar energy 1 into electric energy. Comparing with the prior art, the present invention has the following advantages. It is suitable in any season and can absorb light energy from any orientation with a larger light absorbing area. Furthermore, the present invention has a higher efficiency and the solar energy can be retained well. The light energy can be transferred to a farther place and the present invention is suitable for a wide light wave band.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A solar energy absorbing device, comprising:
a plurality of magnifying glasses which are formed as an integral body and are arranged through 360 degrees so as to absorb solar energy at any orientation and are combined by adhesion or by using a frame for absorbing solar energy;
a plurality of focusing sheets spaced from the magnifying glasses and for focusing the light from the magnifying glasses;
a plurality of optical fibers connected to the focusing sheets for transferring the light focused by the focusing sheets; and
at least one photoelectric converter for converting solar energy into electric energy.

2. The solar energy absorbing device as claimed in claim 1, wherein the photoelectric converter is connected to a DC to AC converter to convert the DC current into AC current so as to be used in an AC device or in an industrial power device, or the power is stored in a solar energy battery.

3. The solar energy absorbing device as claimed in claim 1, wherein the plurality of magnifying glasses are formed as semi-sphere.

4. The solar energy absorbing device as claimed in claim 2, wherein the plurality of magnifying glasses are formed as semi-sphere.

5. The solar energy absorbing device as claimed in claim 1, wherein the focusing sheet is placed at a focus point of a respective magnifying glass for focusing light from the magnifying glass effectively.

6. The solar energy absorbing device as claimed in claim 1, wherein the magnifying glass is connected to the focusing sheet which is installed at an outer side of the magnifying glass.

7. The solar energy absorbing device as claimed in claim 1, wherein the focusing sheet is installed in the magnifying glass.
